(19) United States
(12) Patent Application Publication
(10) Pub. No.: US 2005/0145888 A1
(43) Pub. Date: Jul. 7, 2005

(54) Charge transfer device

(76) Inventor: Yoshiaki Kato, Kusatsu-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/994,282

(22) Filed: Nov. 23, 2004

(30) Foreign Application Priority Data
Dec. 1, 2003 (JP) 2003-401869

(51) Int. Cl. H01L 29/74

(52) U.S. Cl. 257/215

(57) ABSTRACT

The present invention is a charge transfer device that includes: a charge transfer unit 203 that transfers signal charge; a first gate electrode 201 which is formed above the charge transfer unit 203 and controls the transfer; a second gate electrode 202 which is formed, covering an edge of the first gate electrode, above the charge transfer unit 203, and adjacent to the first gate electrode 201; a first wiring portion 208 which is connected to the first gate electrode 201 for applying driving voltage to it; a second wiring portion 209 which is connected to the second gate electrode 202 for applying driving voltage to it. The second wiring portion 209 is formed within an area above the first wiring portion 208 and within an area inward of edges along a length of the first wiring portion 208, or is formed, covering an edge of the first wiring portion 208 with an overlap length which is equal to or shorter than a gate overlap length of the vertical transfer unit 203.

### BACKGROUND OF THE INVENTION

(1) Field of the Invention

The present invention relates to a charge transfer device that can be used for a solid-state imaging device included in a camcorder and a digital steel camera, for example.

(2) Description of the Related Art

Recently, a solid-state imaging device is provided for a wide range of use such as an imaging unit of a camcorder and a digital steel camera. Among them, an Interline Transfer Charge Coupled Device (CCD) solid-state imaging apparatus (hereinafter to be referred to as “IT-CCD”) with small-noise characteristic, is especially focused on.

FIG. 1 is a pattern diagram showing the structure of a general IT-CCD.

In FIG. 1, the IT-CCD1 includes: a photodiode 101 with a photoelectric conversion function, a plurality of which are bi-dimensionally arranged; and a vertical transfer unit 102 with embedment-type channel structure, which is placed adjacently to each photodiode 101 and transfers in a vertical direction signal charge generated in the photodiode 101; a vertical transfer gate 103 which is placed adjacently to each photodiode 101 and controls the vertical transfer; a vertical wiring portion 104 for providing each vertical transfer gate 103 with a transfer pulse that controls the transfer; a horizontal transfer unit 105 for transferring in horizontal direction the signal charge transferred from each vertical transfer unit 102; and an output unit 106 for outputting to the outside the signal charge received from the horizontal transfer unit 105.

FIG. 2 is a diagram showing the photodiode 101 that is equivalent to six unit pixels, and a gate electrode pattern of the vertical transfer gate 103.

FIG. 2 shows a photodiode 204, a first transfer gate 201 made of a first polysilicon, and a second transfer gate 202 made of a second polysilicon, which are formed on the vertical transfer unit 102.

FIG. 3 is a diagram showing the detail of the gate electrode pattern of the vertical wiring portion 104 for providing each vertical transfer gate 103 in FIG. 1 with a driving signal.

FIG. 3 shows, as in FIG. 2, the first transfer gate 201 made of the first polysilicon, the second transfer gate 202 made of the second polysilicon, a first wiring portion 208 made of polysilicon for providing the first transfer gate 201 with driving voltage, and a second wiring portion 209 made of polysilicon for providing the second transfer gate 202 with driving voltage. The first wiring portion 208 and the second wiring portion 209 are electrically connected to an aluminum (AL) wiring 207 via a contact 206. Thus, a transfer pulse is applied for transferring charge in vertical direction to each of the gates.

Vertical transfer pulses of V1-V4 are applied to the AL wiring 207, by which V2 and V4 are applied in turn to the first transfer gate 201 while V1 and V3 are applied in turn to the second transfer gate 202. Note that, in the following description, the second transfer gate to which V1 is applied is referred to as a V1 gate, the first transfer gate to which V2 is applied, as a V2 gate, the second transfer gate to which V3 is applied, as a V3 gate, and the first transfer gate to which V4 is applied, as a V4 gate.

In FIGS. 2 and 3, the first transfer gate 201 and the first wiring portion 208 are made of the first polysilicon while the second transfer gate 202 and the second wiring portion 209 are made of the second polysilicon, respectively. The second transfer gate 202 has an overlap part on the first transfer gate 201, and the second wiring portion 209, on the first wiring portion 208.

The following describes the overlap part.

FIG. 4 shows a gate electrode of the conventional IT-CCD. (b) in FIG. 4 shows a cross section at A-A′ in the vicinity of the center of the vertical transfer unit 203 shown in (a) in FIG. 4.

In FIG. 4, the V1 or V3 gate has an overlap a1 that overlaps with the V2 or V4 gate, while the V2 or V4 gate has an overlap b1 that overlaps with the V3 or V1 gate.

A dielectric film such as an oxidized film is formed in each overlap part between the first transfer gate 201 and the second transfer gate 202. Such dielectric film can be obtained by performing oxidization to the first transfer gate 201 after the formation of the first transfer gate 201, or by forming the second transfer gate 202 after the formation of the dielectric film by use of CVD method or the like.

After the formation of the second transfer gate 202, a dielectric film is further formed between the second transfer gate 202 and the wiring layer located above it by oxidization or the CVD method or the like.

At the time of the oxidization performed on the second transfer gate 202, oxide can be easily provided on the overlap part. The length of the overlap b1 is shorter than that of the overlap a1 so that the dielectric film of the overlap b1 is thicker than that of the overlap a1.

FIG. 5 shows a gate electrode wiring portion of the conventional IT-CCD. (b) in FIG. 5 shows a cross section at B-B′ in the gate electrode wiring portion of the conventional IT-CCD shown in (a) in FIG. 5.

In FIG. 5, the V1 or V3 gate respectively has an overlap a2 that overlaps with the V2 or V4 gate while the V2 or V4 gate respectively has an overlap b2 that overlaps with the V1 or V3 gate.

Note that a semiconductor substrate 205 below the first wiring portion 208 and the second wiring portion 209 is made of silicon.

Comparing the overlaps a2 and b2 shown in FIG. 5 with the overlaps a1 and b1 of the gate electrode in the vertical transfer unit 203 shown in FIG. 4, a2 and a1 have almost the same length, but b2, which is usually set to be almost the same length as a2, is longer than b1. Therefore, the dielectric film of the overlap b2 is not as thick as that of the overlap b1.

Note that, in the vertical transfer unit 203, it is usual that a gate formation is performed with limited space, as in the case of forming photodiodes which are placed adjacently to each other within a unit pixel size. In the wiring portion, however, there being no need to form the photodiodes in such manner, sufficient space is provided. It is therefore usual that the overlaps of the same length are formed. This is described in a patent literature of Japanese Laid-Open Application No. 11-40795.

The problem, however, is that with the charge transfer device in the solid-state imaging apparatus with conventional structure, sufficient strength cannot be obtained for driving voltage, as described below.

That is to say, in the wiring portion, since the gate dielectric films respectively between V4 and V1 as well as V2 and V3 are thinner than the gate dielectric film in the imaging unit, the strength between the gates is reduced in the wiring portion. This causes a problem that a leek is caused between the gates in the wiring portion when a voltage difference between a high-level (VH) voltage and a low-level (VL) voltage is applied.

The technique disclosed in the patent literature mentioned above does not seem to have any problems, since there is no overlap between the gates in the wiring portion that has a contact 206, as shown in FIG. 3. Nevertheless, the overlap sufficient enough to cause this problem is generated in the wiring pattern before it reaches the contact 206.

In the conventional example, in the area having a contact within the wiring portion, the gates are formed so as not to overlap. This can be realized because a size of the unit pixel held as a solid-state imaging apparatus is large enough. Today with progress in miniaturization, however, it is hard to say that such example is an efficient method.

The above problem can be seen not only in the charge transfer unit and the wiring portion in the solid-state imaging apparatus, but is a common problem for the CCD devices in general.

### SUMMARY OF THE INVENTION

An object of the present invention is to provide a charge transfer apparatus which can gain the same strength between gates in the wiring portion as in the imaging unit, and can drive without the problem of generating a leek between the gates, in spite of the miniaturization of unit pixel.

The charge transfer device according to the present invention is a charge transfer device that includes: a semiconductor substrate; a charge transfer unit that is formed on said semiconductor substrate, and is operable to transfer signal charge; a first gate electrode that is formed above said charge transfer unit and controls the transfer; a second gate electrode that is formed, covering an edge of said first gate electrode, above said charge transfer unit, and adjacent to said first gate electrode; and a first wiring portion connected to said first gate electrode for applying driving voltage to said first gate electrode; a second wiring portion connected to said second gate electrode for applying driving voltage to said second gate electrode, wherein said second wiring portion is formed above said first wiring portion, within an area inward of edges along a length of said first wiring portion.

The charge transfer device according to the present invention may further include a photodiode that converts light into signal charge, wherein said charge transfer unit is operable to transfer the signal charge accumulated in said photodiode, and said second wiring portion is formed above said first wiring portion, within an area inward of edges along a length of said first wiring portion, and at least outside a valid pixel area in which said photodiode is formed.

The charge transfer device according to the present invention is also a charge transfer device that includes: a semiconductor substrate; a charge transfer unit that is formed on said semiconductor substrate, and is operable to transfer signal charge; a first gate electrode that is formed above said charge transfer unit, and is operable to control the transfer; a second gate electrode that is formed, covering an edge of said first gate electrode with an overlap length d1, above said charge transfer unit, adjacent to said first gate electrode, and that controls the transfer; a first wiring portion connected to said first gate electrode for applying driving voltage to the first gate electrode; and a second wiring portion connected to said second gate electrode for applying driving voltage to said second gate electrode, wherein said second wiring portion is formed, covering an edge of said first wiring portion with an overlap length d2, the overlap length d2 being equal to or shorter than the overlap length d1.

The charge transfer device according to the present invention may further include a photodiode operable to convert light into signal charge, wherein said charge transfer unit is operable to transfer the signal charge accumulated in said photodiode, and said second wiring portion is formed, covering the edge of said first wiring portion with the overlap length d2, at least outside a valid pixel area in which said photodiode is formed, the overlap length d2 being equal to or shorter than the overlap length d1.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a plain view of the conventional solid-state imaging apparatus (IT-CCD);

FIG. 2 shows a gate electrode pattern of the conventional IT-CCD;

FIG. 3 shows a pattern of the gate electrode wiring portion in the conventional IT-CCD;

(a) in FIG. 4 shows a gate electrode pattern of the conventional IT-CCD while (b) in FIG. 4 shows its cross section;

(a) in FIG. 5 shows a pattern of the gate electrode wiring portion in the conventional IT-CCD while (b) in FIG. 5 shows its cross section;

FIG. 6 shows a pattern of the gate electrode wiring portion in the charge transfer device according to a first embodiment;

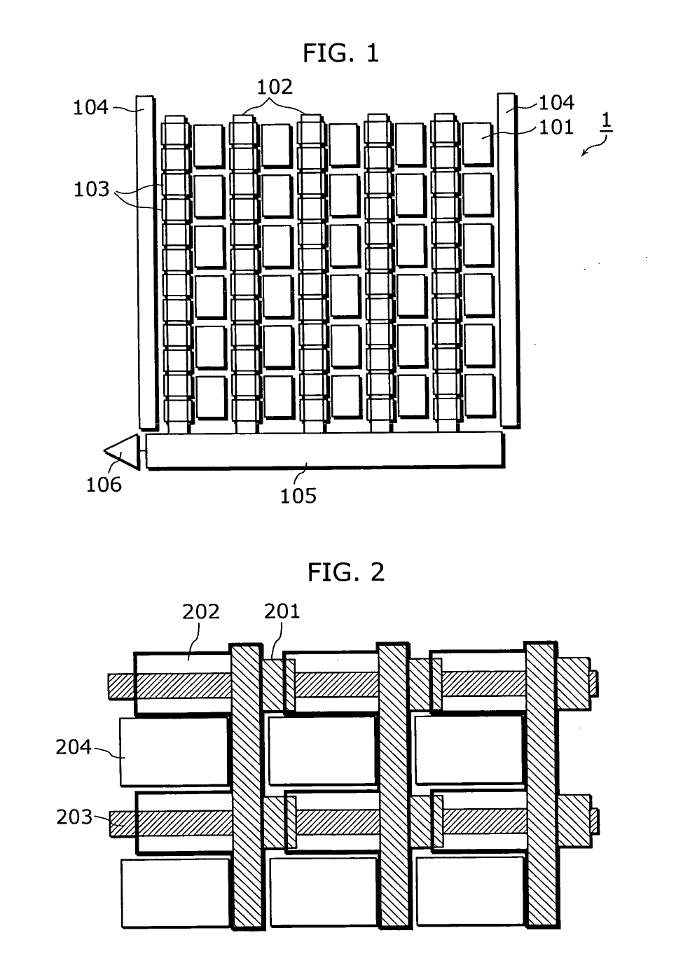

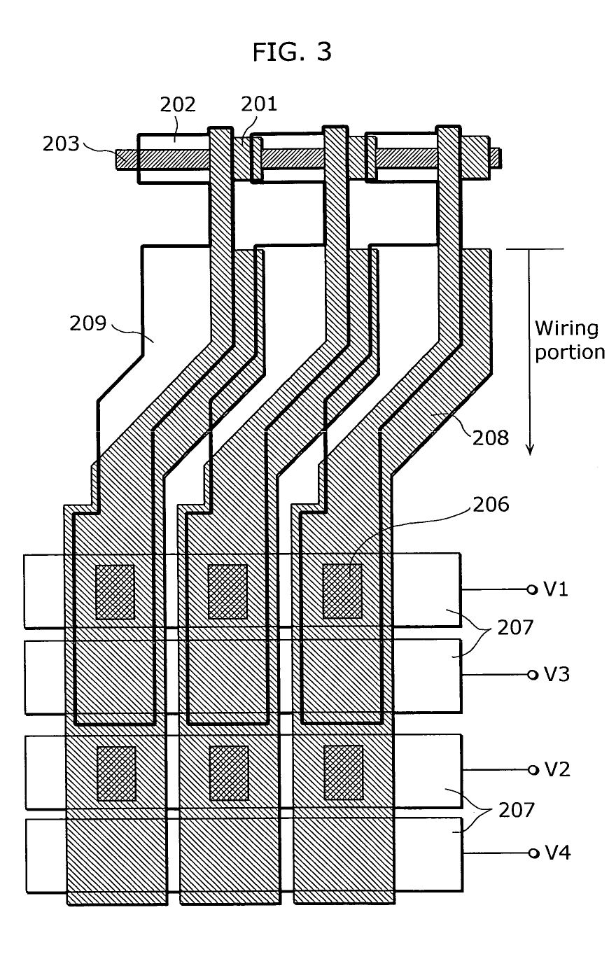

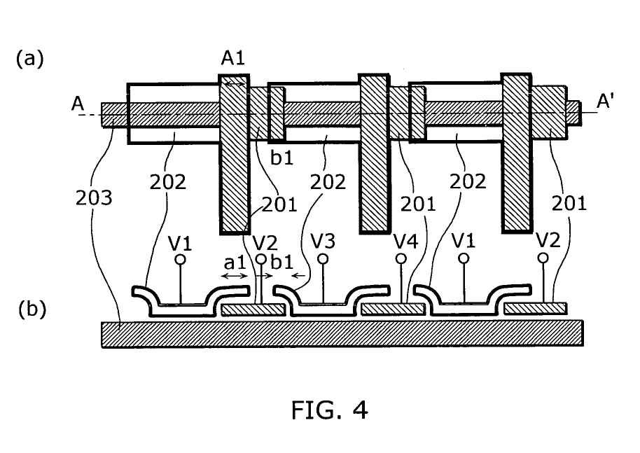

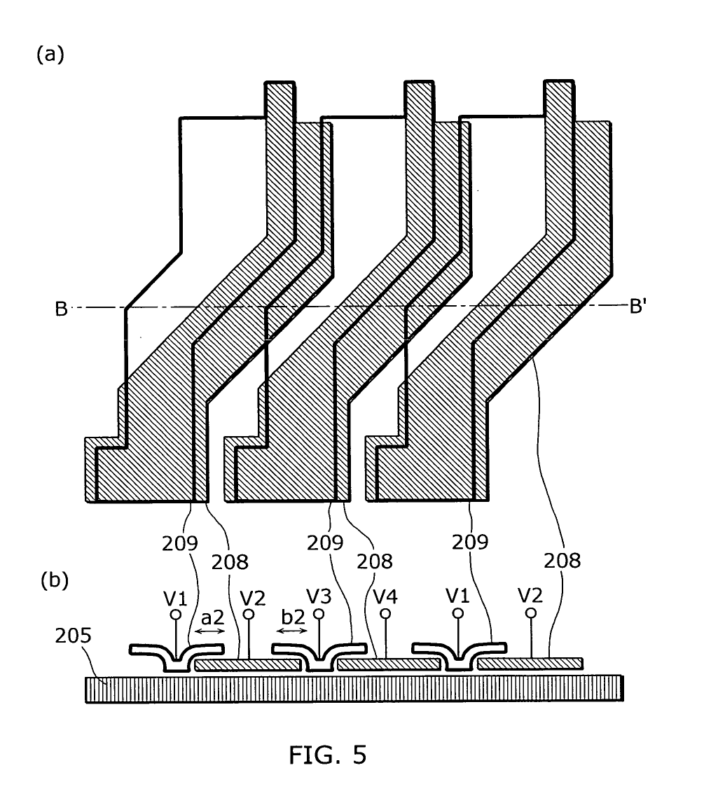

(a) in FIG. 7 shows a pattern of the gate electrode wiring portion in the charge transfer device according to the first embodiment, while (b) in FIG. 7 shows its cross section; and

(a) in FIG. 8 shows a pattern of the gate electrode wiring portion in the charge transfer device according to a second embodiment, while (b) in FIG. 8 shows its cross section.

### DESCRIPTION OF THE PREFERRED EMBODIMENT(S)

The following describes the embodiments of the present invention with reference to the diagrams.

(First Embodiment)

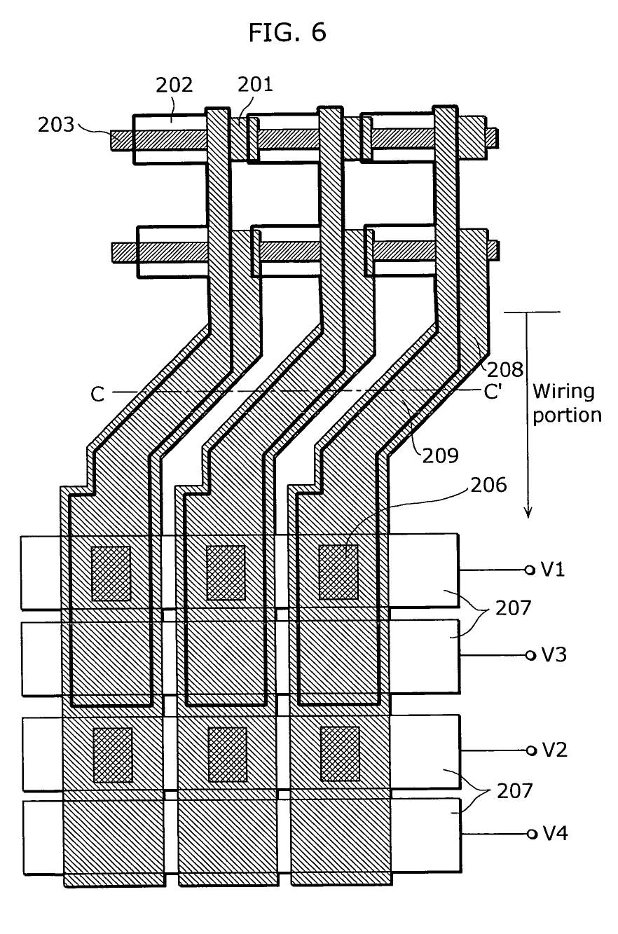

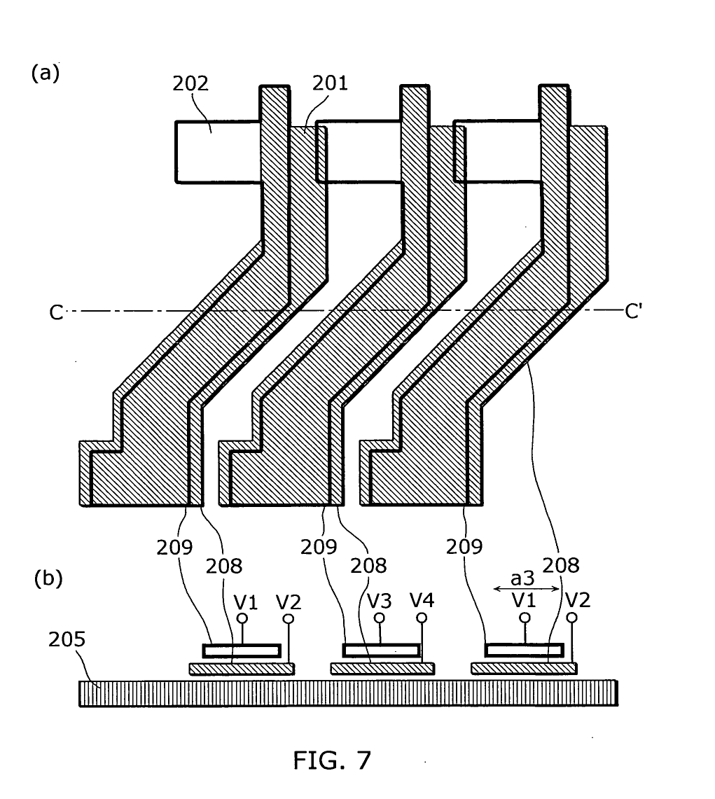

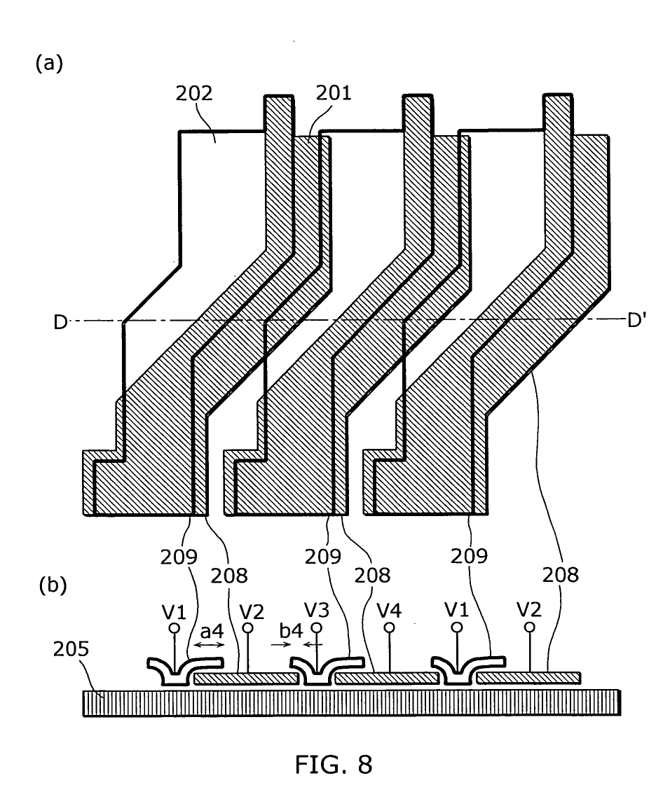

FIG. 6 shows an electrode pattern of the charge transfer device in the solid-sate imaging device according to the first embodiment of the present invention.

FIG. 6 shows the first transfer gate 201 made of polysilicon of a first type, the second transfer gate 202 made of polysilicon of a second type, the first wiring portion 208 made of polysilicon for providing the first transfer gate with driving voltage, and the second wiring portion 209 made of polysilicon of the first type for providing the second transfer gate 202 with driving voltage.

The first wiring portion 208 and the second wiring portion 209 are electrically connected to an aluminum (AL) wiring 207 by a contact 206. Thus, a transfer pulse for transferring charge in vertical direction is applied to each of the gates.

Vertical transfer pulses of V1 to V4 are applied to the AL wiring 207, by which V2 and V4 are applied in turn to the first transfer gate 201 while V1 and V3 are applied in turn to the second transfer gate. Note that, in the following description, the second transfer gate to which V1 is applied is referred to as a V1 gate, the first transfer gate to which V2 is applied, as a V2 gate, the second transfer gate to which V3 is applied, as a V3 gate, and the first transfer gate to which V4 is applied, as a V4 gate.

FIG. 7 shows an electrode pattern of the gate electrode wiring according to the first embodiment of the present invention. (b) in FIG. 7 is a cross-sectional view at C-C′ in the plain view shown in (a) in FIG. 7.

In FIG. 7, the V1 or V3 gate respectively has an overlap a3 where the V1 gate overlaps with the V2 gate or the V3 gate overlaps with the V4 gate, while the V2 gate does not overlap with the V3 gate nor does the V4 gate with the V1 gate.

In the present embodiment, the overlap a3 between the V1 gate and the V2 gate or between the V3 gate and the V4 gate has a width as long as the gate width of the V1 or V3 gate. The width of the V1 or V3 gate is less than or equal to that of the V2 or V4 gate respectively, and the respective V1 and V3 gates are formed within the width of the V2 and V4 gate.

As described above, with the structure of the charge transfer device according to the first embodiment of the present invention, it is possible to realize the charge transfer device that generates no leek between the gates, as seen in the conventional art described with reference to FIG. 5, that can gain the same strength between the gates in the wiring portion as in the imaging unit, and that can be driven without the problem of generating leek between the gates.

(Second Embodiment)

FIG. 8 shows an electrode pattern of the gate electrode wiring in the charge transfer device according to the second embodiment of the present invention. (b) in FIG. 8 is a cross-sectional view at D-D′ in the plain view shown in (a) in FIG. 8.

FIG. 8 shows the first transfer gate 201 made of polysilicon of the first type, the second transfer gate 202 made of polysilicon of the second type, and each pattern formed in each wiring in the first transfer gate 201 and the second transfer gate 202.

As in the first embodiment, V2 or V4 is applied to the first transfer gate 201 while V1 or V3 is applied to the second transfer gate 202.

In FIG. 8, V1 or V3 gate has an overlap a4 where the V1 gate overlaps with the V2 or the V3 gate overlaps with the V4 gate while the V2 or V4 gate has an overlap b4 where the V2 gate overlaps with the V3 gate or the V4 gate overlaps with the V1 gate.

In the present embodiment, the length of the respective overlaps a4 and b4 is as same as that of the respective overlaps a1 and b1 in the vertical transfer unit 203 shown in FIG. 4.

In the first embodiment according to the present invention, V1 and V3 which are the second wiring portions have a structure in which they face each other only on the surface of V2 and V4 which are the first wiring portions, as shown in FIGS. 6 and 7. Therefore, when a high voltage is applied between V1 or V3 and V2 or V4, the electric field concentrates on the corner at which a plane surface and a side surface join in the gate electrode cross-sectional structure, so that a leek is easily generated between the gates that are facing in vertical direction.

According to the structure of the second embodiment of the present invention, however, the second transfer gate 202 does not cover the corner on which the electric field concentrates in the first transfer gate 201 so that there is no such place where the leak is easily generated even when a high voltage is applied between the gates.

The wiring of the vertical transfer gate is the first place where the voltage is externally applied through a metallic wiring such as AL. The voltage is applied thereafter to the whole vertical transfer unit 203 through the gate electrode made of polysilicon and others. Such gate electrode has a relatively high resistance and the speed of applying voltage is moderate in the vertical transfer unit 203.

In this way, the wiring in the vertical transfer gate is the most fragile part in terms of strength between the gates. It is therefore possible to greatly improve the strength in the wiring with the structure according to the present invention.

In the second embodiment of the present invention, the second wiring portion 209 covers, with the overlaps a4 and b4, the corner at which the plane surface and the side surface join in the cross-sectional structure of the first wiring portion 208. The amount of the overlap a4 between V1 and V2 is about 0.5 μm, which is as same as the amount of the overlap a1 between V1 and V2 in the vertical transfer unit 203. The amount of the overlap b4 between V2 and V3 is about 0.2 μm, which is as same as the amount of the overlap b1 between V2 and V3 in the vertical transfer unit 203. Namely, this relationship can be expressed in a1≈a4>b4≈b1.

The amount of overlap b4 between V2 and V3 is small, so that the dielectric film becomes thick due to the oxide provided when a process such as oxidization is performed on the second wiring portion 209.

Therefore, by forming in such manner that the amount of the respective overlaps a4 and b4 are not larger than the amount of the respective overlaps a1 and b1 in the vertical transfer unit 203 shown in FIG. 4, the dielectric film at this part is not thin at the final stage of the formation. It is therefore possible to prevent the degradation in strength in the second wiring portion 209 that covers the corner of the first wiring portion 208.

Although the same driving voltage is applied in the first and second embodiments, the transfer pulses V1 to V4 applies in turn, as vertical transfer pulses, middle (M) voltage and low (L) voltage to each electrode, while high (H) voltage is applied when charge is transferred from the photodiode to the vertical transfer unit 203.

For example, when H voltage is applied between the transfer gates V1 and V3, the wiring between V1 to V2 and the wiring between V3 as well as V4 greatly overlap, and strength becomes relatively small as a result of taking the voltage difference between the neighboring wirings. It is therefore desirable to apply H voltage respectively to V1 and V3 at the time when M voltage is applied to V2 and V4. In the first embodiment of the present invention, the part that covers the corner of the first transfer gate 201 does not exist in the transfer gate wiring, therefore, there is no need to take the voltage between V1 and V2 as well as V3 and V4 into consideration. However, the vertical transfer unit 203 has the part that covers the corner of the first transfer gate 201 so that the consideration related to the driving voltage as mentioned above is effective in any embodiment.

As described above, according to the charge transfer device with the structure illustrated in the first and second embodiments, strength in the overlap part is improved in the wiring as well as in the imaging unit. It is therefore possible to drive without any problems such as leak caused in the wiring when high voltage pulse is applied between the gates.

Note that the present embodiment describes the transfer gate in the case of applying four types of pulses V1 to V4. In view of the difference voltage to be applied to each gate as described in the above case of applying voltage, as well as an amount of the overlap that covers the corner of the gate, the same result can be obtained in the case of using pulses and electrode structure based on arbitrary number of phases.

The present embodiment also describes that the wiring is made of AL, but other low-resistant wiring, such as copper, tungsten, may be used instead.

It is also described that gate material is polysilicon, but polycide or other material can be used.

It should be noted that, as shown in FIGS. 6 and 8, the first wiring portion 208 and second wiring portion 209 on the side of the vertical transfer unit 203 are formed so as to avoid the vicinity of an output unit of the horizontal transfer unit 105 because an area for wiring or circuit has to be retained. The first and second wiring portions 208 and 209, however, may be wired straightly.

The present invention can be applied not only to the charge transfer unit and the wiring in the solid-state imaging apparatus, but to all the CCD devices.

Industrial Applicability

The charge transfer device according to the present invention is applicable to a solid-state imaging apparatus such as IT-CCD. Today with the increased necessity for a thin dielectric between the gates along with the miniaturization of unit pixel, its practicability shall be greatly appreciated.

1. A charge transfer device comprising:
a semiconductor substrate;
a charge transfer unit that is formed on said semiconductor substrate, and is operable to transfer signal charge;
a first gate electrode that is formed above said charge transfer unit and controls the transfer;
a second gate electrode that is formed, covering an edge of said first gate electrode, above said charge transfer unit, and adjacent to said first gate electrode; and
a first wiring portion connected to said first gate electrode for applying driving voltage to said first gate electrode;
a second wiring portion connected to said second gate electrode for applying driving voltage to said second gate electrode,
wherein said second wiring portion is formed above said first wiring portion, within an area inward of edges along a length of said first wiring portion.

2. The charge transfer device according to claim 1, further comprising
a photodiode that converts light into signal charge,
wherein said charge transfer unit is operable to transfer the signal charge accumulated in said photodiode, and
said second wiring portion is formed above said first wiring portion, within an area inward of edges along a length of said first wiring portion, and at least outside a valid pixel area in which said photodiode is formed.

3. A charge transfer device comprising:
a semiconductor substrate;
a charge transfer unit that is formed on said semiconductor substrate, and is operable to transfer signal charge;
a first gate electrode that is formed above said charge transfer unit, and is operable to control the transfer;
a second gate electrode that is formed, covering an edge of said first gate electrode with an overlap length d1, above said charge transfer unit, adjacent to said first gate electrode, and that controls the transfer;
a first wiring portion connected to said first gate electrode for applying driving voltage to the first gate electrode; and
a second wiring portion connected to said second gate electrode for applying driving voltage to said second gate electrode,
wherein said second wiring portion is formed, covering an edge of said first wiring portion with an overlap length d2, the overlap length d2 being equal to or shorter than the overlap length d1.

4. The charge transfer device according to claim 3, further comprising
a photodiode operable to convert light into signal charge,
wherein said charge transfer unit is operable to transfer the signal charge accumulated in said photodiode, and
said second wiring portion is formed, covering the edge of said first wiring portion with the overlap length d2, at least outside a valid pixel area in which said photodiode is formed, the overlap length d2 being equal to or shorter than the overlap length d1.
